(19) United States
(12) Patent Application Publication
(10) Pub. No.: US 2022/0372189 A1
(43) Pub. Date: Nov. 24, 2022

(54) COPOLYMER AND COMPOSITE MATERIAL

(71) Applicant: INDUSTRIAL TECHNOLOGY RESEARCH INSTITUTE, Hsinchu (TW)

(72) Inventors: Wen-Pin TING, Huwei Township (TW); Kuei-Yi CHUANG, Hsinchu City (TW); Shih-Yao LIANG, Taipei City (TW); Yen-Chun LIU, Taipei City (TW)

(73) Assignee: INDUSTRIAL TECHNOLOGY RESEARCH INSTITUTE, Hsinchu (TW)

(21) Appl. No.: 17/497,673

(22) Filed: Oct. 8, 2021

(30) Foreign Application Priority Data
May 6, 2021 (TW) 110116352

(51) Int. Cl. C08F 222/10; C08F 216/12; C08F 222/22; C08F 222/20; C08F 236/04; C08F 222/40

(52) U.S. Cl. CPC C08F 222/1025; C08F 216/125; C08F 222/22; C08F 222/20; C08F 236/04; C08F 222/40; H05K 1/056

(57) ABSTRACT

A copolymer is formed by reacting (A) aromatic monomer, an oligomer thereof, or a polymer thereof, with (B) aliphatic monomer, an oligomer thereof, or a polymer thereof. The aromatic monomer has a chemical structure of

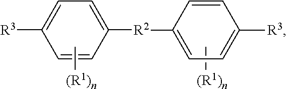

in which each of R¹ is independently H or CH₃, and n=1-4. R² is a single bond, —O—,

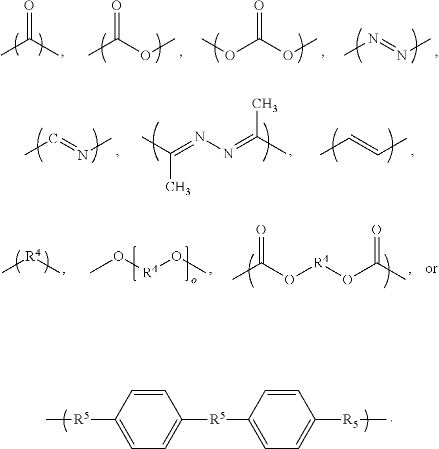

Each of R³ is independently

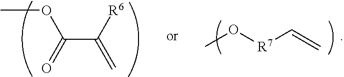

### CROSS REFERENCE TO RELATED APPLICATIONS

The present application is based on, and claims priority from, Taiwan Application Serial Number 110116352, filed on May 6, 2021, the disclosure of which is hereby incorporated by reference herein in its entirety.

### TECHNICAL FIELD

The technical field relates to a copolymer and a composite material.

### BACKGROUND

Circuit boards and IC substrates produced for the optoelectronics and semiconductor industries are trending toward high-speed, high-density, intensive, and high integration because of the rise of the “Cloud”, “Internet” and “Internet of things”, enhancements of 4G and 5G communication technologies, and improvements in display technologies. The required properties of the circuit boards and the IC substrates in the future will be not only low dielectric constant and low loss, but also high insulation and high thermal conductivity. For example, the copper foil substrate in a circuit board is concisely represented as copper foil/dielectric layer/copper foil, and the middle dielectric layer is usually composed of resin, glass fiber, or insulation paper with low thermal conductivity. Therefore, the copper foil substrate has poor thermal conductivity.

A novel thermally conductive resin is called for to increase the thermal conductivity of the dielectric layer between the copper foils.

### SUMMARY

One embodiment of the disclosure provides a copolymer, being formed by reacting (A) aromatic monomer, an oligomer thereof, or a polymer thereof, with (B) aliphatic monomer, an oligomer thereof, or a polymer thereof, wherein the aromatic monomer has a chemical structure of

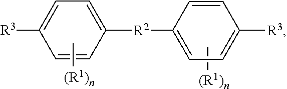

wherein each of R¹ is independently H or CH₃, and n is 1 to 4; R² is a single bond, —O—,

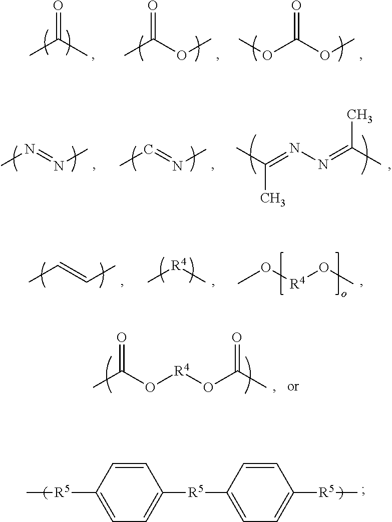

R⁴ is C₂₋₁₀ alkylene group; each of R⁵ is independently a single bond, —O—,

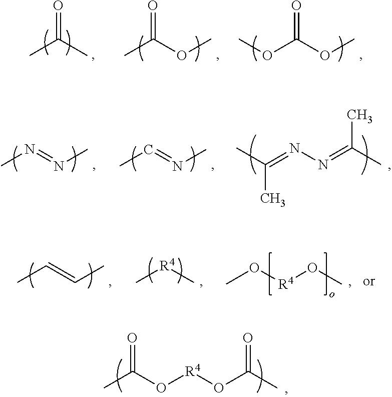

and o is 1 to 70; and each of R³ is independently

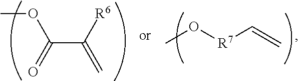

R⁶ is H or CH₃, and R⁷ is C₁₋₁₀ alkylene group.

In some embodiments, the aromatic monomer has a chemical structure of

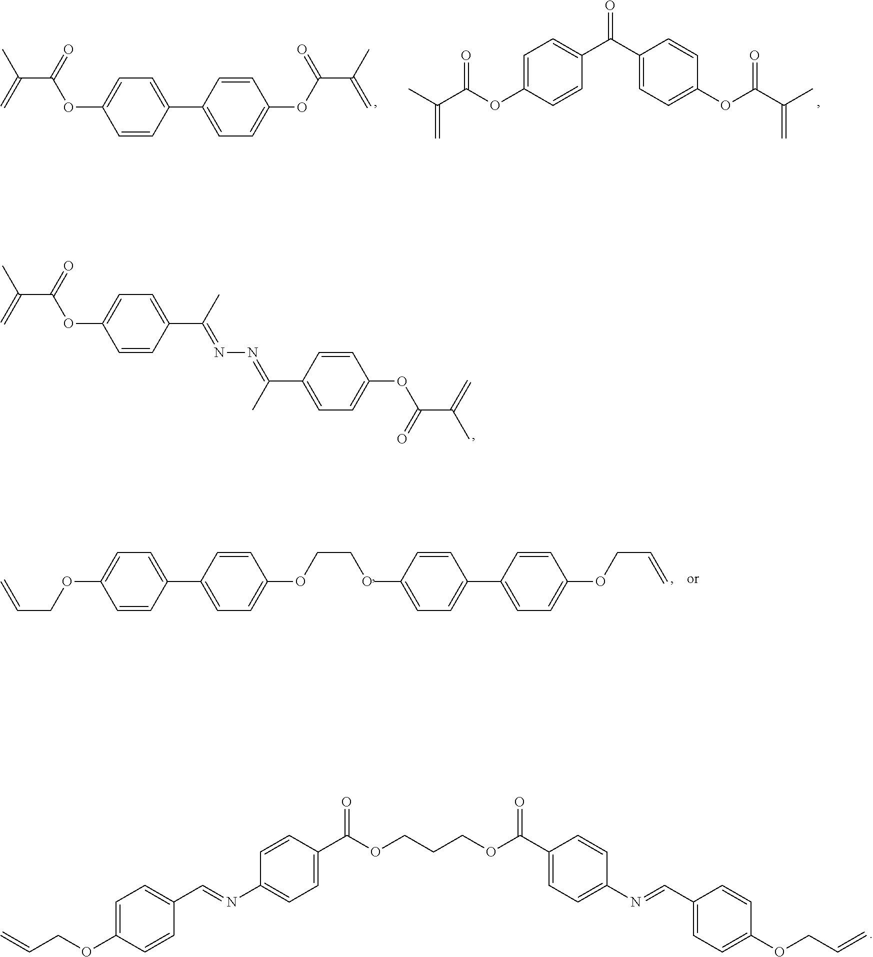

In some embodiments, the aliphatic monomer is 1,3-butadiene, isoprene, 1,3-pentadiene, 2,3-dimethyl-1,3-butadiene, 2-methyl-1,3-pentadiene, 2,3-dimethyl-1,3-pentadiene 4,5-diethyl-1,3-octadiene,

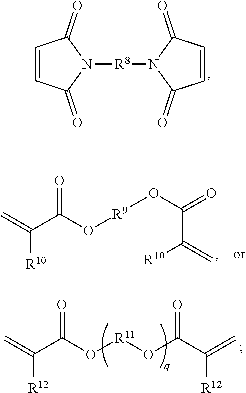

wherein R⁸ is C₁₋₁₂ alkylene group or cycloalkylene group; R⁹ is

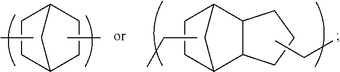

R¹⁰ is H or CH₃; R¹¹ is C₂₋₅ alkylene group; R¹² is H or CH₃; and q is 1 to 70.

In some embodiments, the aliphatic monomer is 1,3-butadiene,

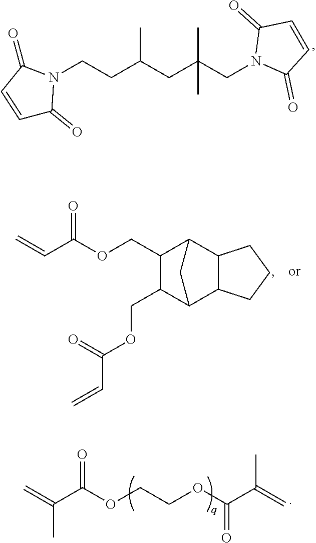

In some embodiments, (A) aromatic monomer, an oligomer thereof, or a polymer thereof and (B) aliphatic monomer, an oligomer thereof, or a polymer thereof have a molar ratio (A/B) of 1:2 to 99:1.

One embodiment of the disclosure provides a composite, including: 1 part by weight of copolymer; and 9 to 99 parts by weight of inorganic powder, wherein the copolymer is formed by reacting (A) aromatic monomer, an oligomer thereof, or a polymer thereof, and (B) aliphatic monomer, an oligomer thereof, or a polymer thereof, wherein the aromatic monomer has a chemical structure of

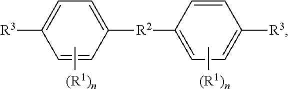

wherein each of R¹ is independently H or CH₃, and n is 1 to 4; R² is a single bond, —O—,

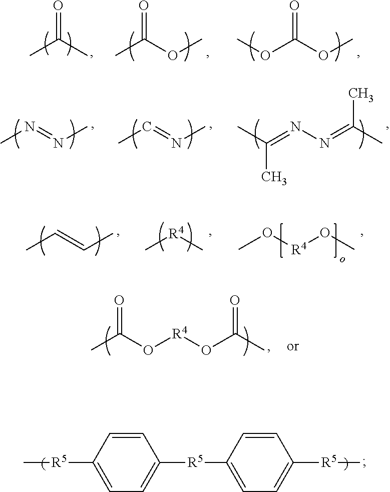

R⁴ is C₂₋₁₀ alkylene group; each of R⁵ is independently a single bond —O—,

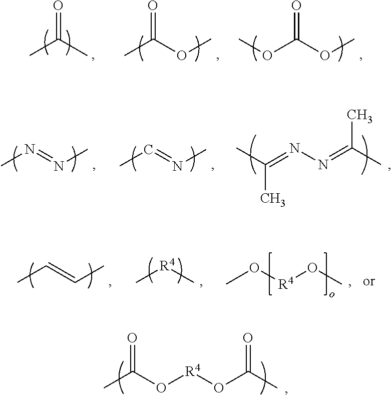

and o is 1 to 70; and each of R³ is independently

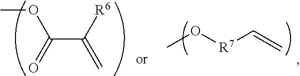

R⁶ is H or CH₃, and R⁷ is C₁₋₁₀ alkylene group.

In some embodiments, the aromatic monomer has a chemical structure of

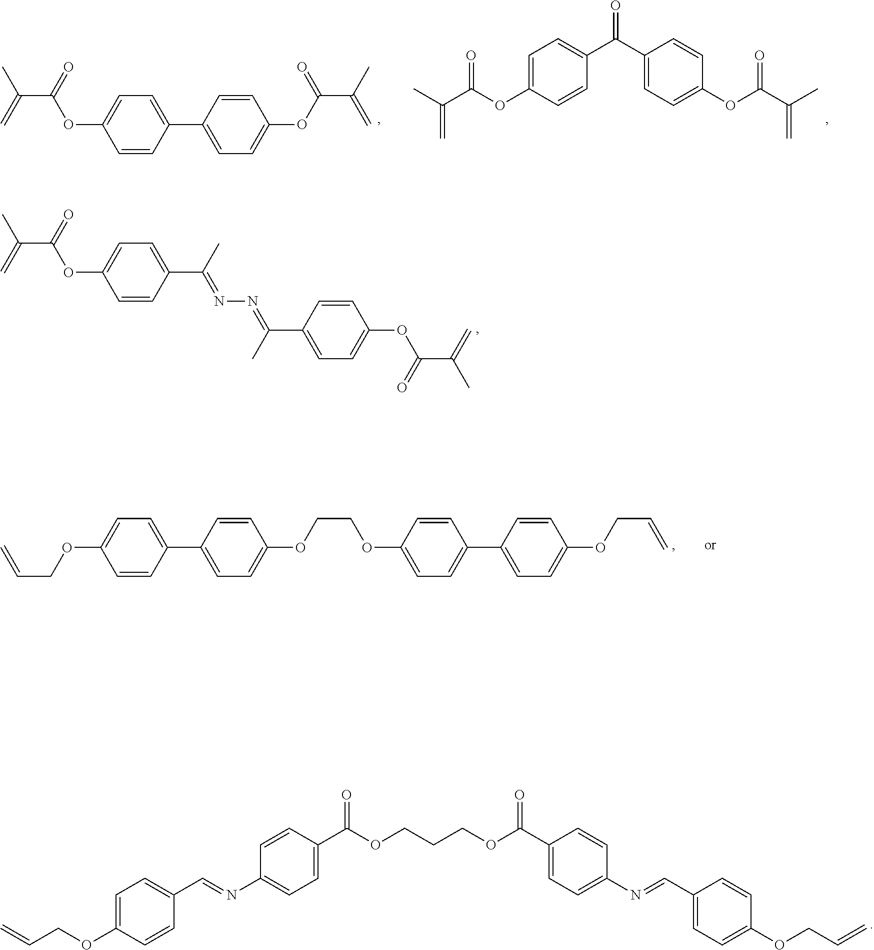

In some embodiments, the aliphatic monomer is 1,3-butadiene, isoprene, 1,3-pentadiene, 2,3-dimethyl-1,3-butadiene, 2-methyl-1,3-pentadiene, 2,3-dimethyl-1,3-pentadiene, 4,5-diethyl-1,3-octadiene,

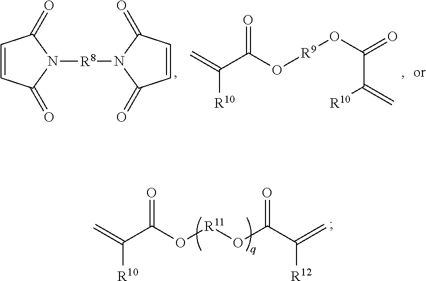

wherein R⁸ is C₁₋₁₂ alkylene group or cycloalkylene group; R⁹ is

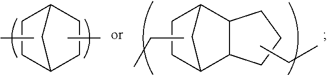

R¹⁰ is H or CH₃; R¹¹ is C₂₋₅ alkylene group; R¹² is H or CH₃; and q is 1 to 70.

In some embodiments, the aliphatic monomer is 1,3-butadiene,

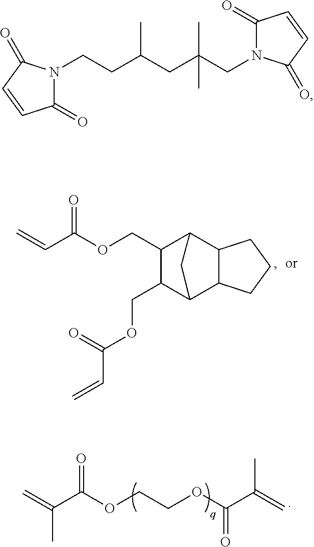

In some embodiments, (A) aromatic monomer, an oligomer thereof, or a polymer thereof and (B) aliphatic monomer, an oligomer thereof, or a polymer thereof have a molar ratio (A/B) of 1:2 to 99:1.

In some embodiments, the inorganic powder includes aluminum nitride, boron nitride, aluminum oxide, magnesium hydroxide, silicon oxide, or a combination thereof.

A detailed description is given in the following embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

One embodiment of the disclosure provides a copolymer, being formed by reacting (A) aromatic monomer, an oligomer thereof, or a polymer thereof, with (B) aliphatic monomer, an oligomer thereof, or a polymer thereof. The aromatic monomer has a chemical structure of

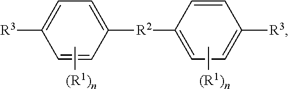

wherein each of R¹ is independently H or CH₃, and n is 1 to 4; R² is a single bond, —O—,

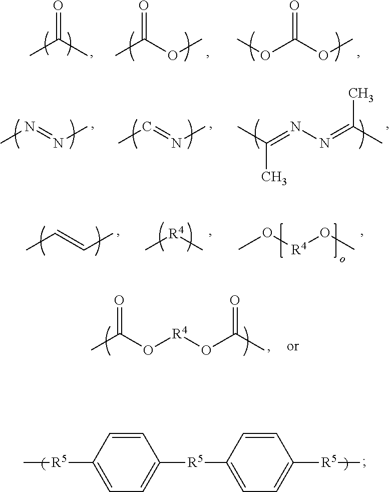

R⁴ is C₂₋₁₀ alkylene group; each of R⁵ is independently a single bond, —O—,

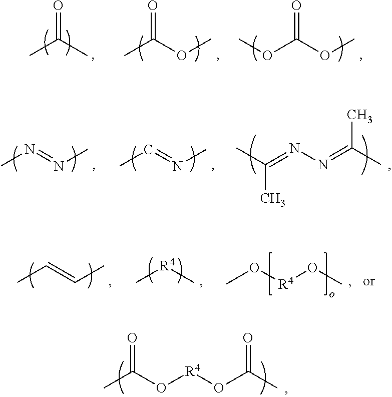

and o is 1 to 70; and each of R³ is independently of

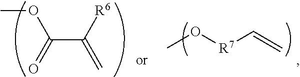

R⁶ is H or CH₃, and R⁷ is C₁₋₁₀ alkylene group.

For Example, the aromatic monomer has a chemical structure of

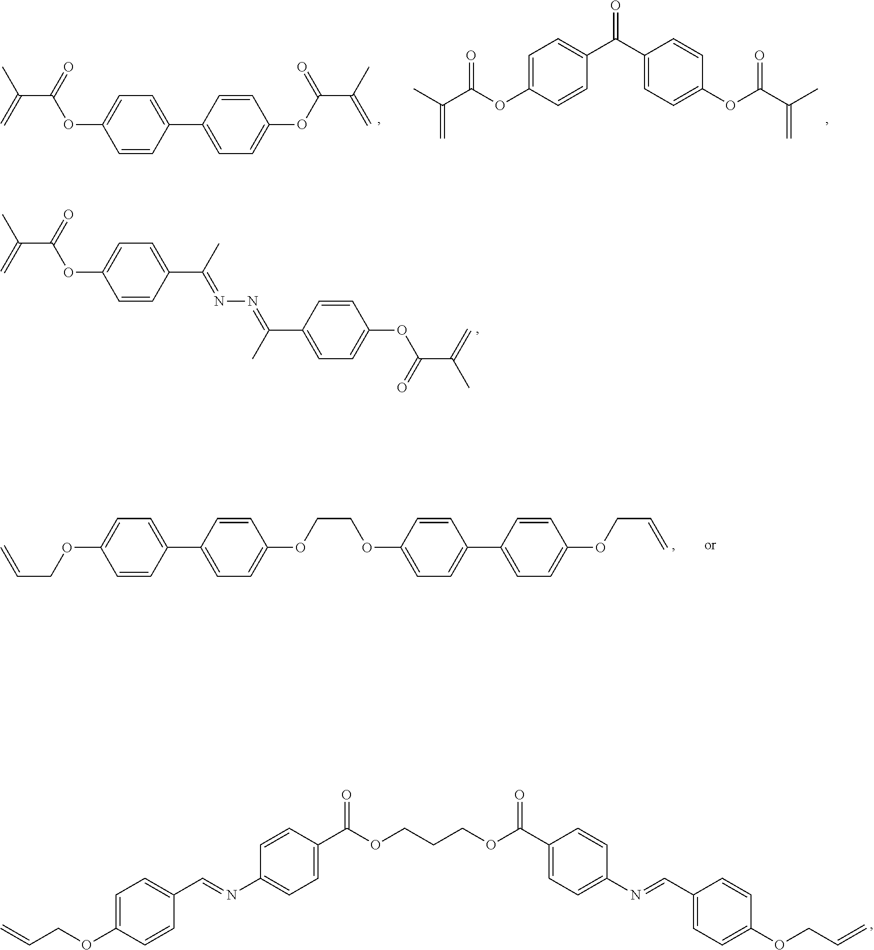

or another suitable aromatic monomer.

In some embodiments, the aliphatic monomer is 1,3-butadiene, isoprene, 1,3-pentadiene, 2,3-dimethyl-1,3-butadiene, 2-methyl-1,3-pentadiene, 2,3-dimethyl-1,3-pentadiene, 4,5-diethyl-1,3-octadiene,

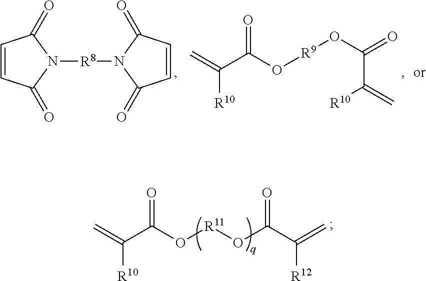

where R⁸ is C₁₋₁₂ alkylene group or cycloalkylene group; R⁹ is

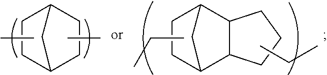

R¹⁰ is H or CH₃; R¹¹ is C₂₋₅ alkylene group; R¹² is H or CH₃; and q is 1 to 70.

For example, the aliphatic monomer is 1,3-butadiene,

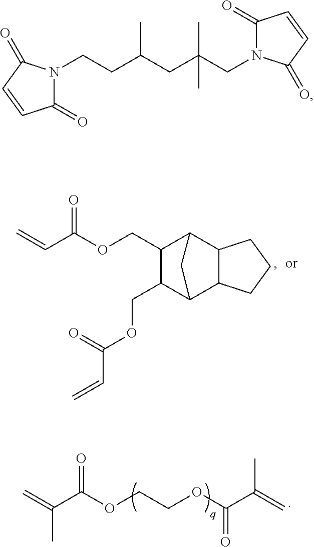

In some embodiments, (A) aromatic monomer, an oligomer thereof, or a polymer thereof and (B) aliphatic monomer, an oligomer thereof, or a polymer thereof have a molar ratio (A/B) of 1:2 to 99:1. If the amount of (A) aromatic monomer, an oligomer thereof, or a polymer thereof is too low, the thermal conductivity of the copolymer will be insufficient (e.g. the heat transfer coefficient (W/mK)<0.3).

One embodiment of the disclosure provides a composite, including: 1 part by weight of copolymer; and 9 to 99 parts by weight of inorganic powder. The copolymer in the composite material can be similar to the described copolymer, and the related description is not repeated here. If the inorganic powder amount is too high, the inorganic powder cannot be uniformly dispersed in the copolymer. In some embodiments, the inorganic powder includes aluminum nitride, boron nitride, aluminum oxide, magnesium hydroxide, silicon oxide, or a combination thereof.

In one embodiment, the copolymer or the composite can be applied as an adhesive or an encapsulation material. In one embodiment, the coating material (containing organic solvent) of the copolymer or the composite material can be coated on a support, and then baking dried to form a coating layer. In some embodiments, the support can be copper foil, polymer film (e.g. polyimide film, polyethylene terephthalate film, or another polymer film), or the like. The coating layer has high thermal conductivity (e.g. heat transfer coefficient (w/mK)≥0.3, or even ≥0.4), low dielectric constant at high frequency (Dk@10 GHz≤3.2, or even ≤2.8), and low dielectric loss at high frequency (Df@10 GHz≤0.003, or even ≤0.0027).

In one embodiment, supports (each includes a coating layer thereon) are laminated, in which the coating layers are contact to each other. When the supports are copper foils, the laminated structure is the so-called copper clad laminate. In one embodiment, the lamination process is performed under a pressure of 5 Kg to 50 Kg at a temperature of 150° C. to 250° C. for a period of 1 hour to 10 hours. In one embodiment, a reinforcing material can be impregnated into the coating material (A-stage). The impregnated reinforcing material is put into an oven at 50.0° C. to 500.0° C., and then baking dried to form a prepreg (B-stage). In one embodiment, the reinforcing material includes glass, ceramic, carbon material, resin, or a combination thereof, and the reinforcing material may have a shape of fiber, powder, sheet, a woven fabric, or a combination thereof. For example, the reinforcing material can be glass cloth. The prepreg has high thermal conductivity (e.g. heat transfer coefficient (W/mK)≥0.3, or even ≥0.4), low dielectric constant under high frequency (Dk@10 GHz≤3.2, or even ≤2.8), and low dielectric constant loss (Df@10 GHz≤0.003, or even ≤0.0027). In one embodiment, one or more prepregs can be interposed between copper foils, and then laminated to form a copper clad laminate. In one embodiment, the lamination process is performed under a pressure of 5 Kg to 50 Kg at a temperature of 150° C. to 250° C. for a period of 1 hour to 10 hours.

Below, exemplary embodiments will be described in detail so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

In the following Examples, the heat transfer coefficient (W/mK) was measured according to the standard ASTM D5470, the dielectric constant at high frequency (DK@10 GHz) was measured according to the standard ASTM D150-11, and the dielectric loss at high frequency (Df@10 GHz) was measured according to the standard ASTM D150-11.

### Synthesis Example a-1

4,4′-Biphenol (186 g, 1 mol), methacrylic anhydride (370 g, 2.4 mol), and sodium hydrogen carbonate (17 g, 0.2 mol) were heated to 80° C. and reacted for 2 hours under nitrogen. 1 L of aqueous solution of sodium hydroxide (2M) was added to the reaction result and left stirring overnight, and then filtered, washed with water, and baking dried to obtain a product (312 g). The ¹H NMR spectrum of the product is shown below: ¹H NMR (400 MHz, CDCl₃): 7.58 (d, 4H, J=8.0 Hz), 7.19 (d, 4H, J=8.0 Hz), 6.37 (s, 2H), 5.77 (s, 2H), 2.08 (s, 6H). The product had a chemical structure of

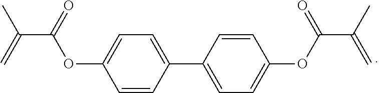 [SMILES: C=C(C)C(=O)Oc1ccc(-c2ccc(OC(=O)C(=C)C)cc2)cc1]

### Synthesis Example a-2

4,4′-Dihydroxyacetophenone (214 g, 1 mol), methacrylic anhydride (370 g, 2.4 mol), and sodium hydrogen carbonate (17 g, 0.2 mol) were heated to 80° C. and reacted for 2 hours under nitrogen. 1 L of aqueous solution of sodium hydroxide (2M) was added to the reaction result and left stirring overnight, and then filtered, washed with water, and baking dried to obtain a product (345 g). The ¹H NMR spectrum of the product is shown below: ¹H NMR (400 MHz, d₆-DMSO): 7.83 (d, 4H, J=8.0 Hz), 7.39 (d, 4H, J=8.0 Hz), 6.30 (s, 2H), 5.95 (s, 2H), 2.02 (s, 6H). The product had a chemical structure of

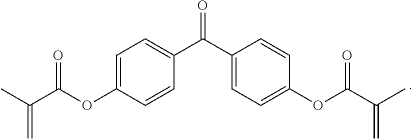 [SMILES: C=C(C)C(=O)Oc1ccc(C(=O)c2ccc(OC(=O)C(=C)C)cc2)cc1]

### Synthesis Example a-3

4-Hydroxyacetophenone (136 g, 1 mol), methacrylic anhydride (185 g, 1.2 mol), and sodium hydrogen carbonate (8.4 g, 0.1 mol) were heated to 80° C. and reacted for 2 hours under nitrogen. 700 mL of aqueous solution of sodium hydroxide (2M) was added to the reaction result and left stirring overnight, and then filtered, washed with water, and baking dried to obtain an intermediate product (198 g, yield=97%). The intermediate product, hydrazine sulfate (64 g, 0.49 mol), and triethylamine (49 g, 0.49 mol) were added to ethanol (200 g), and heated to reflux and react for 5 hours, and then cooled down to room temperature to precipitate solid. The solid was then washed with ethanol and de-ionized water, and then baking dried to obtain a product (120 g). The ¹H NMR spectrum of the product is shown below: ¹H NMR (400 MHz, d₆-DMSO): 7.97 (d, 4H, J=8.0 Hz), 7.26 (d, 4H, J=8.0 Hz), 6.30 (s, 2H), 5.91 (s, 2H), 2.29 (s, 6H), 2.01 (s, 6H). The product had a chemical structure of

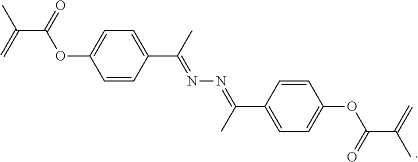 [SMILES: C=C(C)C(=O)Oc1ccc(/C(C)=N/N=C(\C)c2ccc(OC(=O)C(=C)C)cc2)cc1]

### Synthesis Example a-4

4-Biphenol (47 g, 0.25 mol), potassium carbonate (53 g, 0.5 mol), and acetone (100 mL) were mixed and heated to reflux. In addition, 1,3-dibromopropane (20 g, 0.1 mol) was dissolved in acetone (100 mL), which was slowly dripped into the refluxed mixture. After the dropwise addition was completed, the mixture was refluxed and reacted for further 2 hours, and then filtered to remove salt. The filtrate was concentrated to remove solvent to obtain solid, which was washed with water and baking dried to obtain a product (40 g). The ¹H NMR spectrum of the product is shown below: ¹H NMR (400 MHz, d₆-DMSO): 7.40 (d, 4H, J=8.0 Hz), 7.36 (d, 4H, J=8.0 Hz), 6.99 (d, 4H, J=8.0 Hz), 6.78 (d, 4H, J=8.0 Hz), 4.16 (t, 4H, J=4.0 Hz), 2.20-2.16 (m, 2H). The product had a chemical structure of

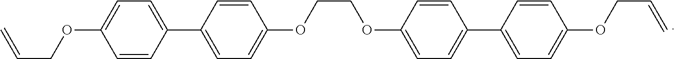 [SMILES: C=CCOc1ccc(-c2ccc(OCCOc3ccc(-c4ccc(OCC=C)cc4)cc3)cc2)cc1]

### Synthesis Example a-5

4-Hydroxybenzaldehyde (122 g, 1 mol), 1-bromopropene (145 g, 1.2 mol), and potassium carbonate (207 g, 1.5 mol), and tetrahydrofuran (THF, 500 mL) were heated to reflux to react under nitrogen for 3 hours, and then filtered to obtain a filtrate. The filtrate was concentrated by a rotary evaporator to remove solvent and obtain 4-allylbenzaldehyde (154 g). 4-Allylbenzaldehyde, 1,3-propanediol bis(4-aminobenzoate) (31.4 g, 0.1 mol), zinc chloride catalyst (5 g) were added to ethanol (500 mL), then heated to reflux to react for 4 hours, then cooled down to room temperature, and then filtered. The filtered precipitate was washed with ethanol and baking dried to obtain a product (55 g). The ¹H NMR spectrum of the product is shown below: ¹H NMR (400 MHz, d₆-DMSO): 8.50 (s, 2H), 7.95 (d, 4H, J=8.0 Hz), 7.86 (d, 4H, J=8.0 Hz), 7.24 (d, 4H, J=8.0 Hz), 7.06 (d, 4H, J=8.0 Hz), 6.10-6.02 (m, 2H), 5.43 (dd, 2H, J=8.0, 1.2 Hz), 5.29 (dd, 2H, J=8.0, 1.2 Hz), 4.66 (d, 4H, J=8.0 Hz), 4.45 (t, 4H, J=4.0 Hz), 2.23-2.18 (m, 2H). The product had a chemical structure of

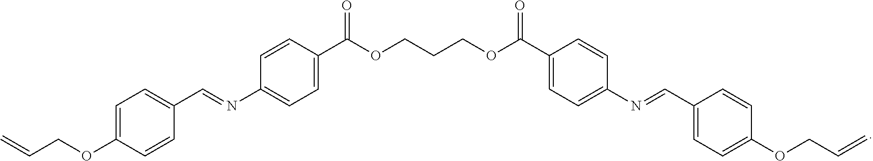 [SMILES: C=CCOc1ccc(/C=N/c2ccc(C(=O)OCCCOC(=O)c3ccc(/N=C/c4ccc(OCC=C)cc4)cc3)cc2)cc1]

### Example 1

322 g of the product in Synthesis Example a-1, 318 g of bismaleimide (BMI-TMH, commercially available from Daiwa Kasei Kogyo Co., Ltd.), and 5 g of a radical initiator 101 (2,5-bis(tert-butyl peroxy)-2,5-dimethylhexane, commercially available from Aldrich) were dissolved in 1000 mL of cyclohexanone, and then refluxed to react for 2 hours to obtain a copolymer. The product in Synthesis Example a-1 and BMI-TMH had a molar ratio of 50:50. The copolymer was coated to form a film with a thickness of 100 m, and then baking dried to form a coating layer, which had a heat transfer coefficient (W/mK) of 0.3, a dielectric constant at high frequency (DK@10 GHz) of 2.36, and a dielectric loss at high frequency (DF@10 GHz) of 0.0021. In addition, the solubility of the copolymer in THE was 67 wt %. BMI-TMH had a chemical structure of

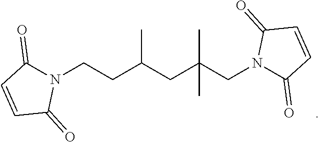 [SMILES: CC(CCN1C(=O)C=CC1=O)CC(C)(C)CN1C(=O)C=CC1=O]

### Example 2

635 g of the product in Synthesis Example a-3, 304 g of poly(ethylene glycol) dimethacrylate (PEGDMA, commercially available from Sigma-Aldrich, Mw=700), and 7 g of the radical initiator 101 were dissolved in 1000 mL of N-methylpyrrolidone (NMP), and then refluxed to react for 2 hours to obtain a copolymer. The product in Synthesis Example a-3 and PEGDMA had a molar ratio of 55:35. The copolymer was coated to form a film with a thickness of 100 m, and then baking dried to form a coating layer, which had a heat transfer coefficient (W/mK) of 0.34, a dielectric constant at high frequency (DK@10 GHz) of 2.42, and a dielectric loss at high frequency (DF@10 GHz) of 0.0023. In addition, the solubility of the copolymer in THE was 65 wt %. PEGDMA had a chemical structure of

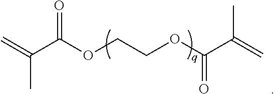

### Example 3

602 g of the product in Synthesis Example a-5, 159 g of BMI-TMH, and 7.6 g of the initiator 101 were dissolved in 1000 mL of dimethylacetamide (DMAc), and then refluxed to react for 2 hours to obtain a copolymer. The product in Synthesis Example a-5 and BMI-TMH had a molar ratio of 50:25. The copolymer was coated to form a film with a thickness of 100 μm, and then baking dried to form a coating layer, which had a heat transfer coefficient (W/mK) of 0.39, a dielectric constant at high frequency (DK@10 GHz) of 2.43, and a dielectric loss at high frequency (DF@10 GHz) of 0.0026. In addition, the solubility of the copolymer in THE was 62 wt %.

### Example 4

492 g of the product in Synthesis Example a-4, 53 g of cycloalkyl acrylate (R-684, commercially available from Nippon Kayaku Co., Ltd.), and 5.5 g of the initiator 101 were dissolved in 1000 mL of NMP, and then refluxed to react for 2 hours to obtain a copolymer. The product in Synthesis Example a-4 and R-684 had a molar ratio of 75:13. The copolymer was coated to form a film with a thickness of 100 m, and then baking dried to form a coating layer, which had a heat transfer coefficient (W/mK) of 0.43, a dielectric constant at high frequency (DK@10 GHz) of 2.4, and a dielectric loss at high frequency (DF@10 GHz) of 0.0028. In addition, the solubility of the copolymer in THE was 60 wt %. R-684 had a chemical structure of

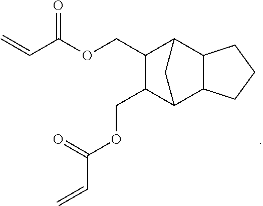 [SMILES: C=CC(=O)OCC1C(COC(=O)C=C)C2CC1C1CCCC12]

### Example 5

347 g of the product in Synthesis Example a-2, 2 g of PEGDMA, and 3.5 g of the initiator 101 were dissolved in 1000 mL of cyclohexanone, and then refluxed to react for 2 hours to obtain a copolymer. The product in Synthesis Example a-2 and PEGDMA had a molar ratio of 99:1. The copolymer was coated to form a film with a thickness of 100 m, and then baking dried to form a coating layer, which had a heat transfer coefficient (W/mK) of 0.45, a dielectric constant at high frequency (DK@10 GHz) of 2.38, and a dielectric loss at high frequency (DF@10 GHz) of 0.0029. In addition, the solubility of the copolymer in THF was 60 wt %.

### Example 6

161 g of the product in Synthesis Example a-1, 175 g of the product in Synthesis Example a-2, 318 g of BMI-TMH, and 4 g of the initiator 101 were dissolved in 1000 mL of cyclohexanone, and then refluxed to react for 2 hours to obtain a copolymer. “The product in Synthesis Example a-1 and the product in Synthesis Example a-2” and BMI-TMH had a molar ratio of 50:50. The copolymer was coated to form a film with a thickness of 100 m, and then baking dried to form a coating layer, which had a heat transfer coefficient (W/mK) of 0.3, a dielectric constant at high frequency (DK@10 GHz) of 2.39, and a dielectric loss at high frequency (DF@10 GHz) of 0.0022. In addition, the solubility of the copolymer in THE was 67 wt %.

### Example 7

100 g of the product in Synthesis Example a-2, 140 g of the product in Synthesis Example a-4, 57 g of PEGDMA, and 3 g of the initiator 101 were dissolved in 1000 mL of NMP, and then refluxed to react for 2 hours to obtain a copolymer. “The product in Synthesis Example a-2 and the product in Synthesis Example a-4” and PEGDMA had a molar ratio of 50:25. The copolymer was coated to form a film with a thickness of 100 m, and then baking dried to form a coating layer, which had a heat transfer coefficient (W/mK) of 0.38, a dielectric constant at high frequency (DK@10 GHz) of 2.36, and a dielectric loss at high frequency (DF@10 GHz) of 0.0024. In addition, the solubility of the copolymer in THE was 63 wt %.

### Example 8

100 g of the product in Synthesis Example a-3, 149 g of the product in Synthesis Example a-5, 2 g of R-684, and 2.5 g of the initiator 101 were dissolved in 1000 mL of NMP, and then refluxed to react for 2 hours to obtain a copolymer. “The product in Synthesis Example a-3 and the product in Synthesis Example a-5” and R-684 had a molar ratio of 99:1. The copolymer was coated to form a film with a thickness of 100 m, and then baking dried to form a coating layer, which had a heat transfer coefficient (W/mK) of 0.42, a dielectric constant at high frequency (DK@10 GHz) of 2.39, and a dielectric loss at high frequency (DF@10 GHz) of 0.0028. In addition, the solubility of the copolymer in THE was 60 wt %.

### Example 9

100 g of the product in Synthesis Example a-2, 140 g of the product in Synthesis Example a-4, 57 g of PEGDMA, and 3 g of the initiator 101 were dissolved in 1000 mL of NMP, and then refluxed to react for 2 hours to obtain a copolymer. “The product in Synthesis Example a-2 and the product in Synthesis Example a-4” and PEGDMA had a molar ratio of 50:25. 300 g of boron nitride and the above copolymer were mixed and then coated to form a film with a thickness of 100 m, and then baking dried to form a coating layer, which had a heat transfer coefficient (W/mK) of 2.41, a dielectric constant at high frequency (DK@10 GHz) of 3.08, and a dielectric loss at high frequency (DF@10 GHz) of 0.0025. The coating layer had a boron nitride content of about 50 wt %.

### Example 10

100 g of the product in Synthesis Example a-2, 140 g of the product in Synthesis Example a-4, 57 g of PEGDMA, and 3 g of the initiator 101 were dissolved in 1000 mL of NMP, and then refluxed to react for 2 hours to obtain a copolymer. “The product in Synthesis Example a-2 and the product in Synthesis Example a-4” and PEGDMA had a molar ratio of 50:25. 700 g of boron nitride and the above copolymer were mixed and then coated to form a film with a thickness of 100 m, and then baking dried to form a coating layer, which had a heat transfer coefficient (W/mK) of 3.24, a dielectric constant at high frequency (DK@10 GHz) of 3.36, and a dielectric loss at high frequency (DF@10 GHz) of 0.0026. The coating layer had a boron nitride content of about 70 wt %.

### Example 11

100 g of the product in Synthesis Example a-2, 140 g of the product in Synthesis Example a-4, 57 g of PEGDMA, and 3 g of the initiator 101 were dissolved in 1000 mL of NMP, and then refluxed to react for 2 hours to obtain a copolymer. “The product in Synthesis Example a-2 and the product in Synthesis Example a-4” and PEGDMA had a molar ratio of 50:25. 1700 g of boron nitride and the above copolymer were mixed and then coated to form a film with a thickness of 100 m, and then baking dried to form a coating layer, which had a heat transfer coefficient (W/mK) of 4.85, a dielectric constant at high frequency (DK@10 GHz) of 3.49, and a dielectric loss at high frequency (DF@10 GHz) of 0.0028. The coating layer had a boron nitride content of about 85 wt %.

### Example 12

20 g of the product in Synthesis Example a-1, 4 g of poly(1,3-butadiene) (NiSSO-PB B1000, commercially available from Nippon Soda Co., Ltd.), and 0.24 g of the initiator 101 were dissolved in 10 mL of NMP, and then refluxed to react for 2 hours to obtain a copolymer. The product in Synthesis Example a-1 and B1000 had a molar ratio of 19:1. The copolymer was coated to form a film with a thickness of 150 m, and then baking dried to form a coating layer, which had a heat transfer coefficient (W/mK) of 0.32, a dielectric constant at high frequency (DK@10 GHz) of 2.24, and a dielectric loss at high frequency (DF@10 GHz) of 0.0026. In addition, the solubility of the copolymer in THE was 65 wt %.

### Comparative Example 1

20 g of the product in Synthesis Example a-1, 174 g of PEGDMA, and 1.8 g of the initiator 101 were dissolved in 1000 mL of cyclohexanone, and then refluxed to react for 2 hours to obtain a copolymer. The product in Synthesis Example a-1 and PEGDMA had a molar ratio of 20:80. The copolymer was coated to form a film with a thickness of 100 m, and then baking dried to form a coating layer, which had a heat transfer coefficient (W/mK) of 0.221, a dielectric constant at high frequency (DK@10 GHz) of 2.44, and a dielectric loss at high frequency (DF@10 GHz) of 0.0031. In addition, the solubility of the copolymer in THF was 66 wt %.

### Comparative Example 2

17 g of the product in Synthesis Example a-4, 40 g of BMI-TMH, and 0.5 g of the initiator 101 were dissolved in 1000 mL of NMP, and then refluxed to react for 2 hours to obtain a copolymer. The product in Synthesis Example a-4 and BMI-TMH had a molar ratio of 20:80. The copolymer was coated to form a film with a thickness of 100 m, and then baking dried to form a coating layer, which had a heat transfer coefficient (W/mK) of 0.227, a dielectric constant at high frequency (DK@10 GHz) of 2.46, and a dielectric loss at high frequency (DF@10 GHz) of 0.0034. In addition, the solubility of the copolymer in THE was 62 wt %.

### Comparative Example 3

10 g of the product in Synthesis Example a-3, 7 g of the product in Synthesis Example a-5, 120 g of R-684, and 1.3 g of the initiator 101 were dissolved in 1000 mL of NMP, and then refluxed to react for 2 hours to obtain a copolymer. “The product in Synthesis Example a-3 and the product in Synthesis Example a-5” and R-684 had a molar ratio of 20:80. The copolymer was coated to form a film with a thickness of 100 m, and then baking dried to form a coating layer, which had a heat transfer coefficient (W/mK) of 0.223, a dielectric constant at high frequency (DK@10 GHz) of 2.48, and a dielectric loss at high frequency (DF@10 GHz) of 0.0036. In addition, the solubility of the copolymer in THF was 61 wt %.

### Comparative Example 4

207 g of the PPE-acrylate (Sabic SA9000, commercially available from Union Chemical Ind. Co., Ltd.), 12 g of poly(1,3-butadiene) (NiSSO-PB B1000, commercially available from Nippon Soda Co., Ltd.), and 2 g of the initiator 101 were dissolved in 1000 mL of NMP, and then refluxed to react for 2 hours to obtain a copolymer. PPE-acrylate and B1000 had a molar ratio of 90:10. The copolymer was coated to form a film with a thickness of 100 m, and then baking dried to form a coating layer, which had a heat transfer coefficient (W/mK) of 0.221, a dielectric constant at high frequency (DK@10 GHz) of 2.44, and a dielectric loss at high frequency (DF@10 GHz) of 0.0042. In addition, the solubility of the copolymer in THE was 65 wt %.

### Comparative Example 5

184 g of the PPE-acrylate (Sabic SA9000, commercially available from Union Chemical Ind. Co., Ltd.), 24 g of poly(1,3-butadiene) (NiSSO-PB B1000, commercially available from Nippon Soda Co., Ltd.), and 2 g of the initiator 101 were dissolved in 1000 mL of NMP, and then refluxed to react for 2 hours to obtain a copolymer. PPE-acrylate and B1000 had a molar ratio of 80:20. The copolymer was coated to form a film with a thickness of 100 m, and then baking dried to form a coating layer, which had a heat transfer coefficient (W/mK) of 0.217, a dielectric constant at high frequency (DK@10 GHz) of 2.46, and a dielectric loss at high frequency (DF@10 GHz) of 0.0037. In addition, the solubility of the copolymer in THE was 65 wt %.

### Comparative Example 6

161 g of the PPE-acrylate (Sabic SA9000, commercially available from Union Chemical Ind. Co., Ltd.), 36 g of B1000, and 2 g of the initiator 101 were dissolved in 1000 mL of NMP, and then refluxed to react for 2 hours to obtain a copolymer. PPE-acrylate and B1000 had a molar ratio of 70:30. The copolymer was coated to form a film with a thickness of 100 m, and then baking dried to form a coating layer, which had a heat transfer coefficient (W/mK) of 0.203, a dielectric constant at high frequency (DK@10 GHz) of 2.48, and a dielectric loss at high frequency (DF@10 GHz) of 0.0034. In addition, the solubility of the copolymer in THE was 65 wt %.

### Comparative Example 7

200 g of the liquid crystal polymer E5204L (commercially available from Sumitomo), 24 g of B1000, and 2 g of the initiator 101 were dissolved in 1000 mL of NMP, and then refluxed to react for 2 hours to obtain a copolymer. E5204L and B1000 had a molar ratio of 70:30. The copolymer was coated to form a film with a thickness of 100 m, and then baking dried to form a coating layer, which had a heat transfer coefficient (W/mK) of 0.23, a dielectric constant at high frequency (DK@10 GHz) of 2.8, and a dielectric loss at high frequency (DF@10 GHz) of 0.0045. In addition, the solubility of the copolymer in THF was 5 wt %.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A copolymer, being formed by
reacting (A) aromatic monomer, an oligomer thereof, or a polymer thereof, with (B) aliphatic monomer, an oligomer thereof, or a polymer thereof,
wherein the aromatic monomer has a chemical structure of 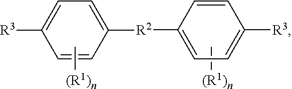
wherein each of R¹ is independently H or CH₃, and n is 1 to 4;
R² is a single bond, —O—, 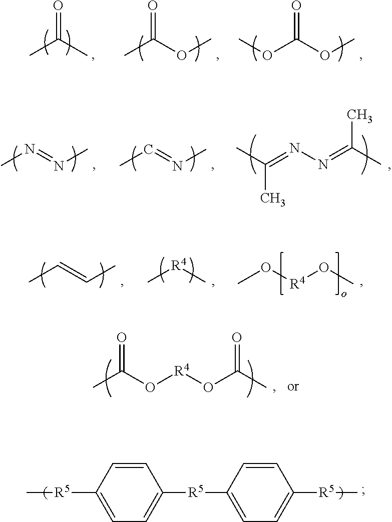
R⁴ is C₂₋₁₀ alkylene group;
each of R⁵ is independently a single bond, —O—, 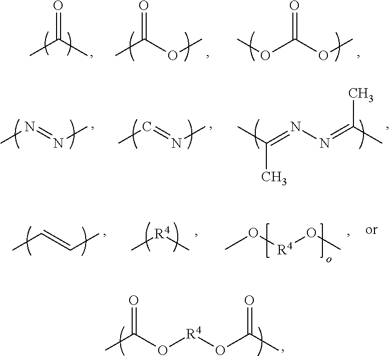
and o is 1 to 70; and
each of R³ is independently 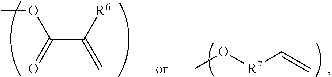
R⁶ is H or CH₃, and R⁷ is C₁₋₁₀ alkylene group.

2. The copolymer as claimed in claim 1, wherein the aromatic monomer has a chemical structure of

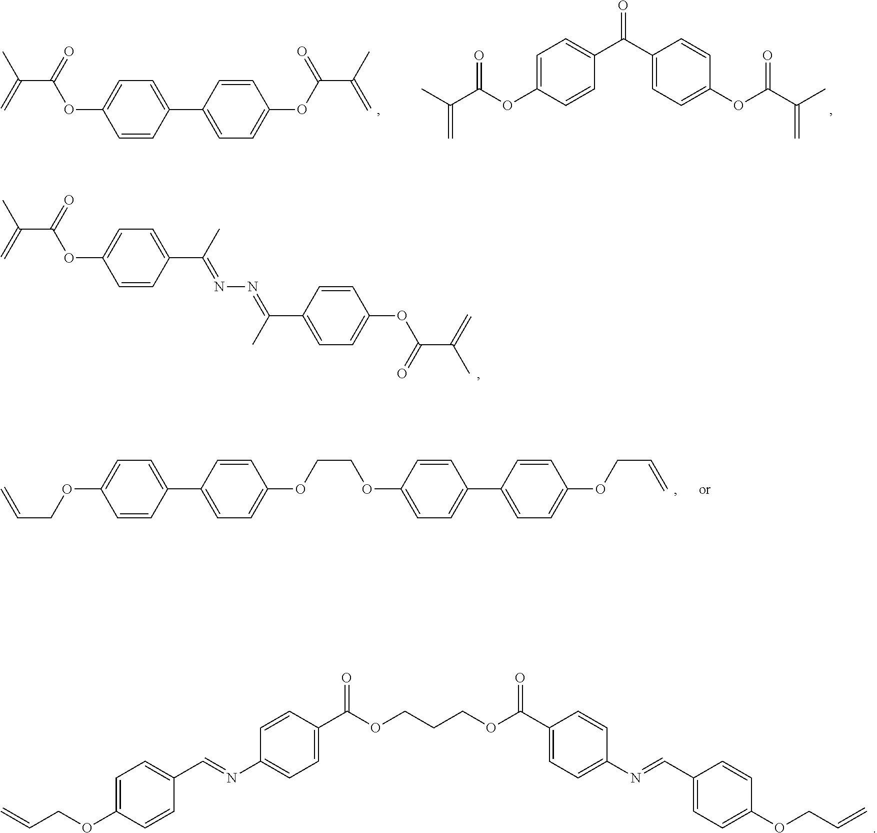

3. The copolymer as claimed in claim 1, wherein the aliphatic monomer is 1,3-butadiene, isoprene, 1,3-pentadiene, 2,3-dimethyl-1,3-butadiene, 2-methyl-1,3-pentadiene, 2,3-dimethyl-1,3-pentadiene, 4,5-diethyl-1,3-octadiene, 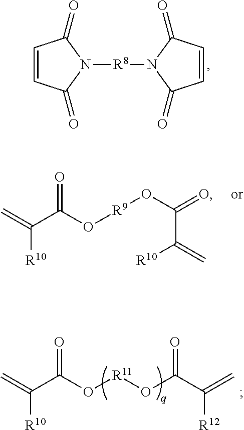
wherein R⁸ is C₁₋₁₂ alkylene group or cycloalkylene group;
R⁹ is 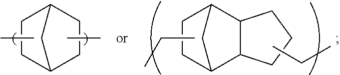
R¹⁰ is H or CH₃;
R¹¹ is C₂₋₅ alkylene group;
R¹² is H or CH₃; and
q is 1 to 70.

4. The copolymer as claimed in claim 3, wherein the aliphatic monomer is 1,3-butadiene,

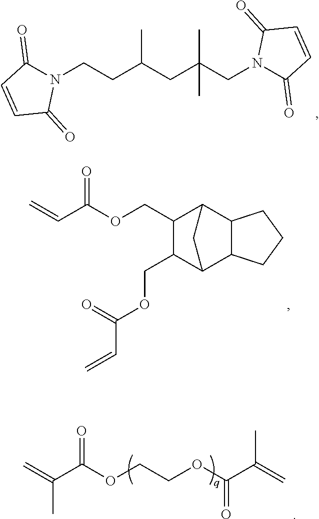

5. The copolymer as claimed in claim 1, wherein (A) aromatic monomer, an oligomer thereof, or a polymer thereof and (B) aliphatic monomer, an oligomer thereof, or a polymer thereof have a molar ratio (A/B) of 1:2 to 99:1.

6. A composite, comprising:
1 part by weight of copolymer; and
9 to 99 parts by weight of inorganic powder,
wherein the copolymer is formed by reacting (A) aromatic monomer, an oligomer thereof, or a polymer thereof, with (B) aliphatic monomer, an oligomer thereof, or a polymer thereof,
wherein the aromatic monomer has a chemical structure of 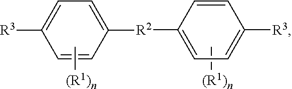
wherein each of R¹ is independently H or CH₃, and n is 1 to 4;
R² is a single bond, —O—, 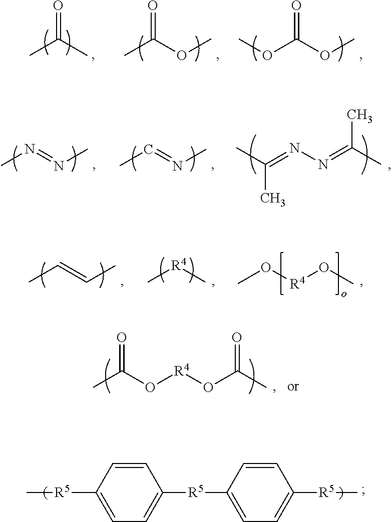
R⁴ is C₂₋₁₀ alkylene group;
each of R⁵ is independently a single bond, —O—, 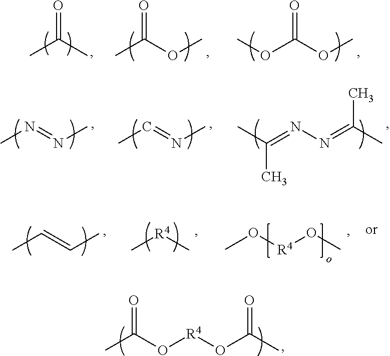
and o is 1 to 70; and
each of R³ is independently 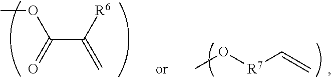
R⁶ is H or CH₃, and R⁷ is C₁₋₁₀ alkylene group.

7. The composite material as claimed in claim 6, wherein the aromatic monomer has a chemical structure of

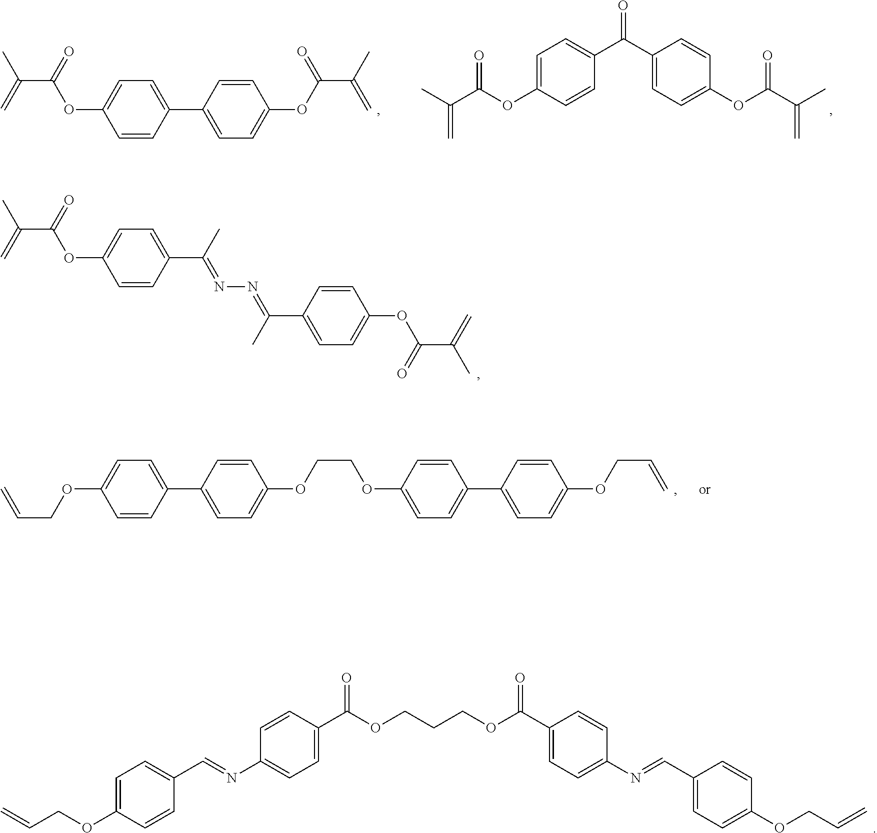

8. The composite material as claimed in claim 6, wherein the aliphatic monomer is 1,3-butadiene, isoprene, 1,3-pentadiene, 2,3-dimethyl-1,3-butadiene, 2-methyl-1,3-pentadiene, 2,3-dimethyl-1,3-pentadiene, 4,5-diethyl-1,3-octadiene, 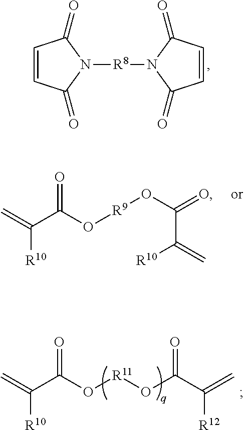
wherein R⁸ is C₁₋₁₂ alkylene group or cycloalkylene group;
R⁹ is 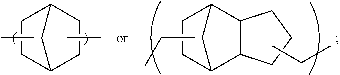
R¹⁰ is H or CH₃;
R¹¹ is C₂₋₅ alkylene group;
R¹² is H or CH₃; and
q is 1 to 70.

9. The composite material as claimed in claim 6, wherein the aliphatic monomer is 1,3-butadiene,

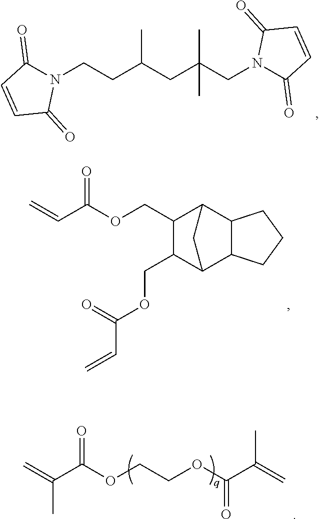

10. The composite material as claimed in claim 6, wherein (A) aromatic monomer, an oligomer thereof, or a polymer thereof and (B) aliphatic monomer, an oligomer thereof, or a polymer thereof have a molar ratio (A/B) of 1:2 to 99:1.

11. The composite material as claimed in claim 6, wherein the inorganic powder comprises aluminum nitride, boron nitride, aluminum oxide, magnesium hydroxide, silicon oxide, or a combination thereof.
